(19) United States
(12) Patent Application Publication
(10) Pub. No.: US 2019/0206586 A1
(43) Pub. Date: Jul. 4, 2019

(54) PATTERNED ELECTRODE, METHOD FOR FORMING PATTERNED ELECTRODE AND DISPLAY DEVICE

(71) Applicant: BOE TECHNOLOGY GROUP CO., LTD., Beijing (CN)

(72) Inventor: Kang GUO, Beijing (CN)

(21) Appl. No.: 16/058,137

(22) Filed: Aug. 8, 2018

(30) Foreign Application Priority Data
Jan. 3, 2018 (CN) 201810004289.2

(51) Int. Cl. H01B 1/04; H01B 5/14; H01B 13/00; H05K 1/02; H05K 1/09; H05K 3/22; H05K 3/00

(52) U.S. Cl. CPC H01B 1/04; H01B 5/14; H01B 13/0036; H05K 1/028; H05K 2201/0323; H05K 3/22; H05K 3/002; H05K 2201/10128; H05K 2203/1142; H05K 1/09

(57) ABSTRACT

The present disclosure provides a patterned electrode, a method for forming a patterned electrode and a display device. The patterned electrode includes: a conductive pattern formed of a conductive material; and an insulation pattern provided in a same layer as the conductive pattern and formed of an insulation material which is transformed from the conductive material.

### CROSS-REFERENCE TO RELATED APPLICATIONS

The present application claims the priority of Chinese Patent Application No. 201810004289.2, filed on Jan. 3, 2018, the contents of which are incorporated herein in their entirety by reference.

### TECHNICAL FIELD

The present disclosure relates to the field of display technology, and in particular to a patterned electrode, a method for forming a patterned electrode and a display device.

### BACKGROUND

Electronic devices including a patterned electrode have been widely used. Generally, the patterned electrode is obtained by a laser etching and/or photolithography process, that is, a layer of conductive material is first formed, and then the conductive material in a partial region is removed by the laser etching and/or photolithography process, the layer of residual conductive material forms the patterned electrode.

### SUMMARY

An embodiment of the present disclosure provides a patterned electrode, including: a conductive pattern formed of a conductive material; and an insulation pattern provided in a same layer as the conductive pattern and formed of an insulation material which is transformed from the conductive material.

In some implementations, the conductive material includes graphene.

In some implementations, the patterned electrode is a flexible electrode layer.

In some implementations, the conductive pattern and the insulation pattern are formed into a single structure, and the insulation pattern is connected to the conductive pattern seamlessly.

In some implementations, both the conductive pattern and the insulation pattern are transparent.

In some implementations, the conductive pattern includes a plurality of parts which are insulated from each other, and the insulation pattern is provided between any adjacent parts of the conductive pattern.

An embodiment of the present disclose provides a method for forming a patterned electrode, including steps of: forming a conductive film layer including a first region and a second region which are not overlapped with each other; forming a protection layer at a first side of the first region of the conductive film layer; transforming the second region of the conductive film layer into an insulation pattern, and the first region of the conductive film layer forms a conductive pattern; and removing the protection layer to obtain the patterned electrode.

In some implementations, the conductive film layer is formed of a transparent conductive material.

In some implementations, the transparent conductive material includes graphene.

In some implementations, the protection layer is formed of a metal material. As an example, the metal material may include any or an alloy of Al, Ni, Cu, Mo and so on.

In some implementations, the step of forming the protection layer includes forming the protection layer by an evaporation plating process.

In some implementations, the step of removing the protection layer includes removing the protection layer by an etching process. As an example, the protection layer may be removed by a wet etching process, and an etching solution used by the wet etching process may include any or a mixture of nitric acid, phosphoric acid, sulfuric acid and so on.

In some implementations, the second region of the conductive film layer is treated by plasma processing under hydrogen to be transformed into the insulation pattern.

In some implementations, a condition for the plasma processing under hydrogen includes that, a flow rate of the hydrogen ranges from 100 sccm to 300 sccm, a pressure of the hydrogen ranges from 200 mTorr to 400 mTorr, and a time for the plasma processing ranges from 30 s to 1200 s.

In some implementations, the first region includes a plurality of parts, and the second region is provided between any adjacent parts of the first region.

An embodiment of the present disclosure provides a display device including the patterned electrode according to the embodiment of the present disclosure.

### DESCRIPTION OF DRAWINGS

FIG. 1 shows a structural diagram of a patterned electrode in an embodiment of the present disclosure;

FIG. 2 shows another structural diagram of a patterned electrode in an embodiment of the present disclosure;

FIGS. 3 and 4 respectively show a flowchart of a method for forming a patterned electrode according to an embodiment of the present disclosure.

### DESCRIPTION OF EMBODIMENTS

In order to make a person skilled in the art understand technical solutions of the present disclosure better, the present disclosure will be described in detail below in conjunction with accompanying drawings and specific embodiments.

In a case where a layer of conductive material is first formed and then the conductive material in a partial region is removed by a laser etching and/or photolithography process such that the layer of residual conductive material forms the patterned electrode, there is a significant difference between optical properties of the region in which the conductive material is retained (i.e., the region where the patterned electrode is located) and the region in which the conductive material is removed. Even if the patterned electrode is formed as transparent by using transparent conductive material, that is, the patterned electrode is transparent theoretically, it also produces an inevitable impact on the light transmitting through it, thus in a case where the light transmits through the patterned electrode, there is still a certain difference between optical contrasts of the region where the transparent patterned electrode is located and the region in which the conductive material is removed.

Additionally, the laser etching process cannot be carried out in a large area, and the photolithography process may result in a problem of photoresist residue, a problem in which a solution for stripping off photoresist increases the square resistance of the patterned electrode, and so on.

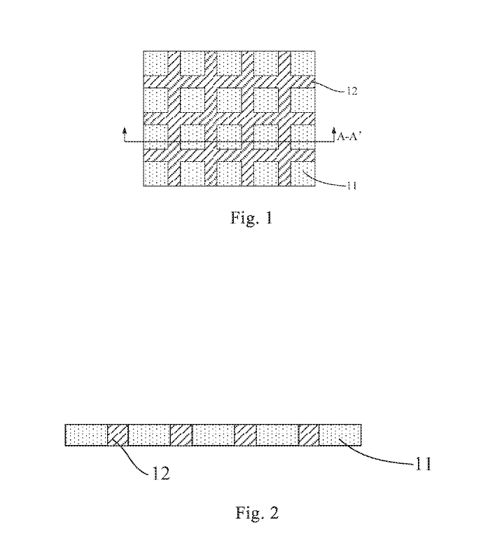

An embodiment of the present disclosure provides a patterned electrode. FIG. 1 shows a top view of the patterned electrode, and FIG. 2 shows a sectional view taken along line A-A′ in FIG. 1. As shown in FIGS. 1 and 2, the patterned electrode includes a conductive pattern 11 and an insulation pattern 12 which are formed in a single layer, the conductive pattern 11 is formed of a conductive material, and the insulation pattern 12 is formed of an insulation material which is transformed from the conductive material.

In some implementations, as shown in FIGS. 1 and 2, the conductive pattern 11 may include a plurality of parts which are insulated from each other, and the insulation pattern 12 is provided between any adjacent parts of the conductive pattern 11.

As shown in FIG. 1, an entire layer of material is formed into the patterned electrode, the material in a partial region of the entire layer is conductive thus forms the conductive pattern 11 for realizing a function of transmitting a signal, and the material in the other region of the entire layer is transformed to be insulative thus forms the insulation pattern 12. Since the insulation pattern 12 exists in the patterned electrode and is formed in a same layer as the conductive pattern 11, the difference between optical properties of the conductive pattern 11 and the insulation pattern 12 is much small, and in a case where the entire layer of material is transparent, when the light transmits through the entire layer of material, the difference between optical contrasts of the region where the conductive pattern 11 is located and the region where the insulation pattern 12 is located is also much small.

In some implementations, the conductive pattern 11 may be formed of graphene, and in such case, the insulation pattern 12 is formed of an insulation material which is transformed from graphene.

In some implementations, the conductive pattern 11 may be formed of indium tin oxide (ITO), and in such case, the insulation pattern 12 is formed of an insulation material which is transformed from ITO.

ITO has a high light transmittance, but includes indium which is expensive, and additionally, ITO has a high brittleness, thus the flexibility of the patterned electrode formed of ITO is not desired.

Graphene is of a two-dimensional planar structure composed of carbon atoms in a single layer, has an extremely high light transmittance (up to 97.7%) and an excellent flexibility, thus is a desired material for a flexible transparent electrode layer. For example, a layer of graphene is formed, and then the layer of graphene may be patterned by an etching process to form the patterned electrode, in such case, there is a significant difference between optical contrasts of the region in which the graphene is etched and the region in which the graphene forms the patterned electrode when the light transmits through these regions. By contrast, in a case where the patterned electrode is formed by transforming the graphene in a partial region of the layer of graphene into an insulation material, when the light transmits the patterned electrode, the difference between optical contrasts of the region in which the graphene is transformed into the insulation material and the region in which the graphene is not transformed into the insulation material is much small, because the graphene which is transformed into the insulation material still exists in the patterned electrode.

In some implementations, the conductive pattern 11 and the insulation pattern 12 are formed into a single structure, and the insulation pattern 12 is fully filled in a gap between any adjacent parts of the conductive pattern 11.

That is to say, as shown in FIG. 1, an entire layer of graphene is formed first, and then the graphene in a partial region of the layer of graphene is transformed into the insulation material, the graphene in the other region of the layer of graphene forms the conductive pattern 11, the insulation material (i.e., the insulation pattern 12) which is transformed from the graphene is filled between any adjacent parts of the conductive pattern 11.

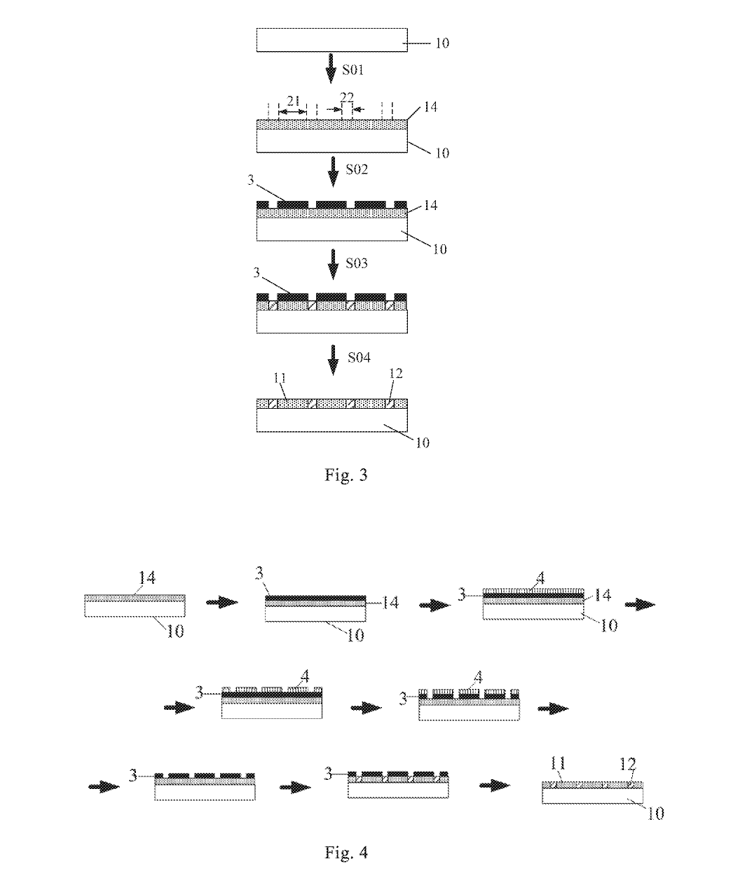

An embodiment of the present disclosure provides a method for forming a patterned electrode. As shown in FIGS. 3 and 4, the method for forming the patterned electrode includes following steps S01 through S04.

S01, forming a conductive film layer 14 including a first region 21 and a second region 22 on a substrate 10, the first region 21 including a plurality of parts, and the second region 22 being provided between any adjacent parts of the first region 21. For example, an entire film layer of graphene is transferred onto the substrate 10 to obtain the conductive film layer 14. The substrate 10 may be a glass substrate, or may be a composite substrate of glass and PI, glass and PET or the like. The film layer of graphene may be in directly contact with the substrate 10, or there may be a substance (e.g., silane coupling agent) between the film layer of graphene and substrate 10 for improving attachment of the graphene and the substrate 10.

In some implementations, the conductive film layer 14 is formed of transparent conductive material. In such case, the patterned electrode which is obtained by patterning the conductive film layer 14 has much small impact on light transmittance when it is applied in a display region of a display device. Certainly, the conductive film layer 14 may be formed of ITO. However, since ITO is expensive and has a high brittleness, when the patterned electrode is to be used for a flexible display device, the conductive film layer 14 may be formed of graphene.

It should be noted that, the first region 21 and the second region 22 are designed and divided for subsequent procedure.

Descriptions below are given by taking the conductive film layer 14 being formed of graphene, and processes in a case where the conductive film layer 14 is formed of any other transparent conductive material are similar thereto.

S02, forming a protection layer 3 at a first side of the first region 21 of the conductive film layer 14.

As shown in FIGS. 3 and 4, the first side of the conductive film layer 14 is a side of the conductive film layer 14 which is distal to the substrate 10. The protection layer 3 can protect the graphene in the first region 21 from changing during subsequent procedure.

In some implementations, the protection layer 3 is formed of a metal material. That is, the graphene may be protected by the metal material. In some implementations, the metal material includes any or an alloy of Al, Ni, Cu, Mo and so on. However, the protection layer 3 is not limited to any particular material, as long as it can protect the graphene in the first region 21 from changing during subsequent procedure.

In some implementations, the protection layer 3 may be formed by an evaporation plating process.

It should be noted that, the pattern of the protection layer 3 is in consistent with that of the first region 21. That is, the protection layer 3 is not an entire layer. As shown in FIG. 3, the protection layer 3 formed of the metal material may be formed by the evaporation plating process, that is, a metal pattern in consistent with the pattern of the first region 21, as the protection layer 3, may be evaporated on the film layer of graphene.

As shown in FIG. 4, the protection layer 3 formed of the metal layer may also be formed by an etching process. For example, an entire metal layer may be formed at the first side of the conductive film layer 14, that is, covers the first region 21 and the second region 22, then a photoresist layer 4 is formed on the metal layer, the photoresist layer 4 is patterned by processes such as exposure, development, then the exposed portion of the metal layer is etched, and the photoresist layer 4 is removed, thus the patterned protection layer 3 (i.e., the protection layer 3 which only covers the first region 21) is obtained.

S03, transforming the second region 22 of the conductive film layer 14 into an insulation pattern 12, and the first region 21 of the conductive film layer 14 forms a conductive pattern 11.

For example, the graphene in the second region 22 is treated by plasma processing under hydrogen to be transformed into the insulation pattern 12. In some implementations, a condition for the plasma processing under hydrogen may include that, a flow rate of the hydrogen ranges from 100 sccm to 300 sccm, a pressure of the hydrogen ranges from 200 mTorr to 400 mTorr, and a time for the plasma processing ranges from 30 s to 1200 s.

During the plasma processing under hydrogen (H₂), H atoms react with the graphene so that the constitution of the graphene changes, thus the graphene change into non-zero-band-gap insulation material from zero-band-gap conductive material.

In some implementations, the plasma processing may be performed under a mixture gas including hydrogen, and the content of Hydrogen may range from 5% to 30%. In some implementations, the time for the plasma processing may range from 900 s to 1200 s.

It should be understood that, when the conductive film layer 14 is formed of any other conductive material, the graphene in the second region 22 may be treated by other corresponding processing to be transformed into the insulation pattern 12, or the graphene in the second region 22 may be treated by the plasma processing to be transformed into the insulation pattern 12, but parameters of the plasma processing may be correspondingly changed.

S04, removing the protection layer 3 in the first region 21, so that the patterned electrode is obtained.

In some implementations, the protection layer 3 in the first region 21 may be removed by a wet etching process. For example, the wet etching process is performed by using an etching solution, and the etching solution includes any or a mixture of nitric acid, phosphoric acid, sulfuric acid and so on. The protection layer 3 may be dipped into the etching solution for a time ranging from 100 s to 140s, so that the etching solution reacts with the protection layer 3 and the protection layer 3 is removed.

In the method for forming the patterned electrode in accordance with the embodiment of the present disclosure, the layer of graphene is patterned without employing the etching process, and the plasma processing is performed on the graphene which is not protected by the metal layer under hydrogen, the conductive pattern and the insulation pattern are formed thus the patterned electrode is formed while maintaining the integrity of the layer. With the method for forming the patterned electrode in accordance with the embodiment of the present disclosure, the difference between optical contrasts of the conductive pattern and the insulation pattern while the light transmits through the patterned electrode is reduced or avoided. Additionally, no photoresist is used for patterning the layer of graphene in the method for forming the patterned electrode in accordance with the embodiment of the present disclosure, thus the problem of photoresist residue and the problem in which the solution for stripping off the photoresist is in contact with the layer of graphene to increase the square resistance of the layer of graphene are avoided.

It should be noted that, although the square resistance of monolayer graphene is larger than that of double-layer or triple-layer graphene, since the layer of graphene is patterned in the method for forming the patterned electrode in accordance with the embodiment of the present disclosure without employing the etching process, no impact is produced on the square resistance of the layer of graphene, the patterned electrode of the embodiment of the present disclosure may be formed of monolayer graphene which has a light transmittance up to 97.7%. By contrast, in a case where the patterned electrode is formed by the etching process, since the solution for stripping off photoresist in the etching process may increase the square resistance of the patterned electrode (e.g., the layer of graphene), in order to avoid the square resistance of the patterned electrode being too large, the patterned electrode may be formed of double-layer or triple-layer graphene.

Thicknesses, sizes of the layers shown in the drawings are exemplary, and the present disclosure is not limited thereto. The present disclosure is also not limited by geometries of the layers shown in the drawings, as desired, a rectangle shown in the drawings may be substituted by a trapezoid or any other shape.

An embodiment of the present disclosure provides a display device including the patterned electrode according to the embodiment of the present disclosure. The display device may be any product or member having a display function, such as liquid crystal display panel, electronic paper, OLED panel, mobile phone, tablet computer, television, display, notebook computer, digital photo frame, navigator and so on.

It should be understood that, the above embodiments and implementations are merely exemplary for explaining principle of the present disclosure, but the present disclosure is not limited thereto. Various modifications and improvements may be made by those ordinary skilled in the art within the spirit and essence of the present disclosure, these modifications and improvements fall into the protection scope of the present disclosure.

1. A patterned electrode, comprising:
a conductive pattern formed of a conductive material; and
an insulation pattern provided in a same layer as the conductive pattern and formed of an insulation material which is transformed from the conductive material,
wherein the conductive material comprises only graphene.

2. (canceled)

3. The patterned electrode of claim 1, wherein the patterned electrode is a flexible electrode layer.

4. The patterned electrode of claim 1, wherein the conductive pattern and the insulation pattern are formed into a single structure, and the insulation pattern is connected to the conductive pattern seamlessly.

5. The patterned electrode of claim 1, wherein both the conductive pattern and the insulation pattern are transparent.

6. The patterned electrode of claim 1, wherein the conductive pattern includes a plurality of parts which are insulated from each other, and the insulation pattern is provided between any adjacent parts of the conductive pattern.

7. A method for forming a patterned electrode, comprising steps of:
forming a conductive film layer including a first region and a second region which are not overlapped with each other;
forming a protection layer at a first side of the first region of the conductive film layer;
transforming the second region of the conductive film layer into an insulation pattern, and the first region of the conductive film layer forms a conductive pattern; and
removing the protection layer to obtain the patterned electrode,
wherein the conductive film layer is formed of a transparent conductive material, and the transparent conductive material comprises only graphene.

8-9. (canceled)

10. The method of claim 7, wherein the protection layer is formed of a metal material.

11. The method of claim 7, wherein the second region of the conductive film layer is treated by plasma processing under hydrogen to be transformed into the insulation pattern.

12. The method of claim 11, wherein a condition for the plasma processing under hydrogen comprises that, a flow rate of the hydrogen ranges from 100 sccm to 300 sccm, a pressure of the hydrogen ranges from 200 mTorr to 400 mTorr, and a time for the plasma processing ranges from 30 s to 1200 s.

13. The method of claim 7, wherein the step of forming the protection layer comprises forming the protection layer by an evaporation plating process.

14. The method of claim 7, wherein the step of removing the protection layer comprises removing the protection layer by an etching process.

15. The method of claim 7, wherein the first region comprises a plurality of parts, and the second region is provided between any adjacent parts of the first region.

16. A display device, comprising the patterned electrode of claim 1.
